(19) United States
(12) Patent Application Publication
(10) Pub. No.: US 2010/0216309 A1
(43) Pub. Date: Aug. 26, 2010

(54) CMP POLISHING LIQUID AND METHOD FOR POLISHING SUBSTRATE USING THE SAME

(75) Inventors: Hisataka Minami, Ibaraki (JP); Hiroshi Ono, Ibaraki (JP); Jin Amanokura, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: HITACHI CHEMICAL COMPANY, LTD., Tokyo (JP)

(21) Appl. No.: 12/678,555

(22) PCT Filed: Oct. 21, 2008
(86) PCT No.: PCT/JP2008/069022

§ 371 Date: Mar. 17, 2010

(30) Foreign Application Priority Data
Oct. 23, 2007 (JP) 2007-275296
Apr. 1, 2008 (JP) 2008-095461

(51) Int. Cl. H01L 21/304; C09K 13/04; C09K 3/14

(52) U.S. Cl. 438/693; 252/79.1; 252/79.2; 257/E21.23

(57) ABSTRACT

Disclosed is a CMP polishing liquid for polishing a substrate having a layer containing ruthenium, comprising: an oxidizing agent; polishing particles; water; and a compound having a structure represented by the following Formula (1), or a salt thereof. This CMP liquid is improved in at least the polishing rate to a ruthenium layer when compared with conventional polishing liquid. Also disclosed is a method for polishing a substrate using such a CMP polishing liquid.

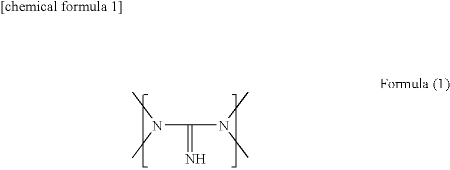

### TECHNICAL FIELD

The present invention relates to a CMP polishing liquid for polishing a substrate having a layer containing ruthenium, and a method for polishing a substrate, using the same.

### BACKGROUND ART

In recent years, new fine processing techniques have been developed as the integration degree of semiconductor integrated circuits (LSIs) and the performance thereof have been made higher. Chemical mechanical polishing (CMP) is one of the techniques. CMP is a technique used frequently in the production of LSIs, in particular, in the planarization of an interlayer insulating film layer, the formation of metallic plugs, and the formation of buried wiring in the step of forming multi level interconnections (see, for example, the specification of U.S. Pat. No. 4,944,836).

In order to make the integration degree and the performance of LSIs high, attempts have been recently made for making use of copper or copper alloy as an interconnection material instead of conventional aluminum alloy. However, copper or copper alloy is not easily subjected to fine processing based on dry etching, which is frequently used to form conventional aluminum alloy interconnections. Thus, the so-called damascene process is mainly adopted, which is a process of depositing a copper or copper alloy layer, which may be referred to merely as a copper layer hereinafter, by electroplating, on an insulating film layer in which grooves (concave regions) are beforehand made, so as to be buried into the grooves, and then removing the copper layer in regions (convex regions) other than the groove regions by CMP, so as to form buried wirings (see, for example, JP-A No. 02-278822).

In an ordinary method for the CMP of a semiconductor substrate on which a copper layer is formed, a polishing pad is first attached onto a circular polishing table (platen), and the surface of the polishing pad is impregnated with a polishing liquid. Next, the copper layer surface of the substrate is pushed against the polishing pad, and the polishing table is rotated in the state that a predetermined pressure (polishing pressure or pressing load) is applied from the rear surface of the substrate to the substrate. Thus, by mechanical friction between the polishing liquid and the copper layer deposited on convex regions of the insulating film layer, the copper layer on the convex regions is removed.

A polishing liquid, used in CMP, for a metal wiring such as copper is generally composed of an oxidizing agent and solid polishing particles. If necessary, a metal-oxide-dissolving agent, and a protective film forming agent (metal anticorrosive) are added thereto. The surface of a copper layer is first oxidized with the oxidizing agent, and the oxidized layer is ground away with the solid polishing particles. This is considered to be a basic mechanism.

The oxidized layer on the copper layer surface on grooves (concave regions) does not contact the polishing pad very much, so that the grinding-away effect of the solid polishing particles is not produced thereon. However, about the oxidized layer on the copper layer surface on convex regions, which contacts the polishing pad, the grinding-away thereof advances. Accordingly, with the advance of the CMP, the copper layer on the convex regions is removed so that the substrate surface is planarized (see, for example, Journal of Electrochemical Society, vol. 138, No. 11 (published in 1991), pp. 3460-3464).

As an underlying layer of the copper layer, a layer made of for example, tantalum, tantalum alloy, tantalum nitride or some other tantalum compound is formed, as a barrier layer for preventing the diffusion of copper into the insulating film layer, by physical vapor deposition (PVD) or the like. As illustrated in FIG. 1, a thin film layer made of copper or copper alloy, which is called a copper seed layer 12, is generally formed between a copper layer 11 and a barrier layer 13 by PVD or the like since the copper layer has low adhesiveness to the barrier layer. In FIG. 1, reference number 14 represents an insulating film layer.

PVD, which is used to form the barrier layer or the copper seed layer, has a problem that when a film is formed thereby, the upper space of any groove made in the insulating film layer is made narrow. Thus, as wiring has been becoming finer, the capability that copper or copper alloy is buried by electroplating has been deteriorating. As a result, voids have been more remarkably generated. As a means for solving this problem, an investigation has been made about a method using ruthenium, ruthenium alloy, or a ruthenium compound, which is excellent in adhesiveness onto copper, instead of the copper seed layer or for forming a layer between the copper seed layer and the barrier layer (FIG. 2 and FIG. 3). In FIG. 2 and FIG. 3, a layer of ruthenium, a ruthenium alloy and a ruthenium compound (hereinafter, a layer containing ruthenium, examples of which include ruthenium, ruthenium alloy, and ruthenium compound layers, may be referred to merely as a “ruthenium layer”) may be formed by chemical vapor deposition (CVD) or atomic layer deposition (ALD). Thus, the layer can cope with the formation of fine wiring.

In the meantime, about regions (convex regions) between interconnections, which are other than the interconnection regions where copper or copper alloy is buried, it is necessary to remove the ruthenium layer and the barrier layer that are made uncovered by CMP. Any platinum group metal layer such as a ruthenium layer is higher in hardness than any copper layer; thus, according to a conventional polishing liquid wherein polishing materials used for copper layers are combined with each other, a sufficient polishing rate is not obtained in many cases.

Thus, a polishing liquid is desired which is capable of making the polishing rate to a ruthenium layer better than the polishing rate in the case of using the conventional polishing liquid. As an attempt for applying CMP to a platinum group metal layer, which contains ruthenium or the like, known is, for example, a method using a polishing liquid into which a diketone, a heterocyclic compound, a urea compound and an amphoteric compound are added (see, for example, the specification of U.S. Pat. No. 6,527,622). However, the polishing liquid is small in the polishing rate to a platinum metal layer. Thus, the liquid does not necessarily satisfy required performances.

In the case of polishing, for example, a substrate as illustrated in FIG. 2, which has a barrier layer 3, a ruthenium layer 2 and a copper layer 1 over an insulating film layer 4, the use of the above-mentioned polishing liquid, which contains a diketone and the like, may make the polishing rate to the copper layer 1 too large but does not give a large polishing rate to the ruthenium layer 2. In the case of trying to polish continuously the copper layer 1, the ruthenium layer 2 and the barrier layer 3 by use of the conventional polishing liquid, wherein polishing materials for polishing copper are combined with each other, an excessive film-decrease (dishing) of the copper layer 1 may be generated.

Thus, an investigation is being made about a method of polishing a substrate having the ruthenium layer 2 as illustrated in FIG. 2, at two separated stages composed of a first step of polishing the copper layer 1 mainly, and a second step of polishing the barrier layer 3 mainly (a two-stage polishing method).

In the first step, the copper layer 1 is polished into such a degree that the copper layer 1 remains slightly as illustrated in FIG. 3(a); or the layer 1 is polished until the ruthenium layer 2 is made uncovered as illustrated in FIG. 3(b).

In the second step, the ruthenium layer 2 and the barrier layer 3 in regions other than groove regions are polished at least until the whole of the barrier layer 3 is lost as illustrated in FIG. 3(c). In the second step, the insulating film layer 4 may be further polished (the so-called over-polishing) as the need arises.

The polishing liquid used in the first step is required to be capable of polishing a copper layer at a high speed and further polishing convex regions selectively, and not to give a large dishing to the copper layer. On the other hand, the polishing liquid used in the second step is required to be capable of polishing a ruthenium layer and a barrier layer at a high speed and further to polish each of a copper layer, the ruthenium layer, the barrier layer and an insulating film layer at a desired polishing rate, and is desirably required to restrain the dishing of the copper layer and a film-decrease (erosion) of the barrier layer and the insulating film layer.

Thus, desired is a polishing liquid making the following possible: when a copper layer, a barrier layer, an insulating film layer and the like need to be polished besides a ruthenium layer, the polishing rate to the ruthenium layer is improved, and further the above-mentioned requirements are satisfied.

### DISCLOSURE OF THE INVENTION

Accordingly, an object of the present invention is to provide a CMP polishing liquid capable of making at least the polishing rate to a ruthenium layer better than the polishing rate in the case of using the conventional polishing liquid. Another object thereof is to provide a CMP polishing liquid capable of polishing each of a metal wiring layer (for example, a copper layer), a ruthenium layer, a barrier layer and an insulating film layer at a desired polishing rate as the need arises as well as making the polishing rate to the ruthenium layer better than that in the case of using the conventional polishing liquid.

Still another object of the invention is to provide a polishing method capable of making at least the polishing rate to a ruthenium layer better than the polishing rate in the case of using the conventional polishing method. A further object thereof is to provide a polishing method capable of polishing each of a metal wiring layer (for example, a copper layer), a ruthenium layer, a barrier layer and an insulating film layer at a desired polishing rate as the need arises as well as making the polishing rate to the ruthenium layer better than that in the case of using a conventional polishing method.

Inventors of the invention have made eager investigations so as to complete the invention on the basis of an idea that a compound having a guanidine structure or a salt thereof is added to a conventional polishing liquid, thereby making it possible that in the CMP of a substrate having a ruthenium layer, a ruthenium complex is generated so that ruthenium is easily dissolved in the polishing liquid.

Accordingly, the invention relates to a CMP polishing liquid for polishing a substrate having a layer containing ruthenium, comprising: an oxidizing agent; polishing particles; water; and a compound having a structure represented by the following Formula (1), or a salt thereof.

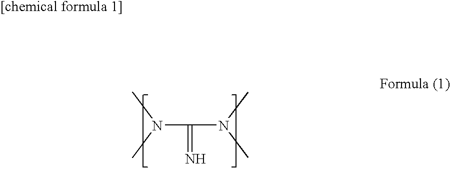

The compound is preferably a compound represented by the following Formula (2),

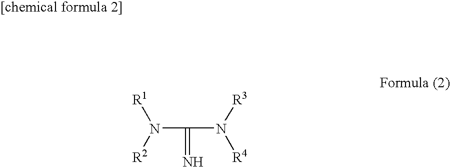

wherein R¹, R², R³ and R⁴ each independently represent a monovalent organic group.

It is preferred that the CMP polishing liquid contains, as the oxidizing agent, at least one selected from the group consisting of hydrogen peroxide, periodic acid, salts of periodic acid, salts of iodic acid, salts of bromic acid, salts of persulfuric acid, and cerium nitrate salts. It is also preferred that the liquid contains, as the polishing particles, at least one selected from the group consisting of alumina, silica, ceria, titania, and zirconia.

The CMP polishing liquid may further contain a metal-oxide-dissolving agent.

The compound contained in the CMP polishing liquid has a resonance structure, and the number of atoms constituting the resonance structure is preferably 4 or more.

The invention also relates to a method for polishing a substrate, comprising the step of polishing a surface of the substrate to be polished in the state of pushing the surface of the substrate to be polished against a polishing cloth on a polishing table and applying pressure to the substrate from the substrate surface opposite to the surface to be polished, while supplying the above-mentioned CMP polishing liquid between the surface to be polished and the polishing cloth by moving the substrate and/or the polishing table.

According to the polishing liquid and the polishing method of the invention, the polishing rate to a ruthenium layer can be made better than according to a case where the conventional polishing liquid or polishing method is used. Furthermore, according to one embodiment of the polishing liquid and the polishing method of the invention, in the case of polishing a metal wiring layer, a barrier layer, an insulating film layer and/or the like besides a ruthenium layer, each of the metal wiring layer, the ruthenium layer, the barrier layer, and the insulating film layer can be polished at a desired polishing rate as well as the polishing rate to the ruthenium layer can be improved.

### BRIEF DESCRIPTION OF THE DRAWINGS

FIG. 1 illustrates a sectional view of a substrate wherein a copper seed layer is formed to keep the adhesiveness between a copper layer and a barrier layer.

FIG. 2 is a sectional view of a substrate wherein a ruthenium layer is formed instead of the copper seed layer.

FIGS. 3(a) to 3(c) are schematic views illustrating an example of a CMP polishing method.

FIGS. 3(a) and 3(b) are each a sectional view illustrating a state of a substrate after a first polishing step, and FIG. 3(c) is a sectional view illustrating a state of the substrate after a second polishing step.

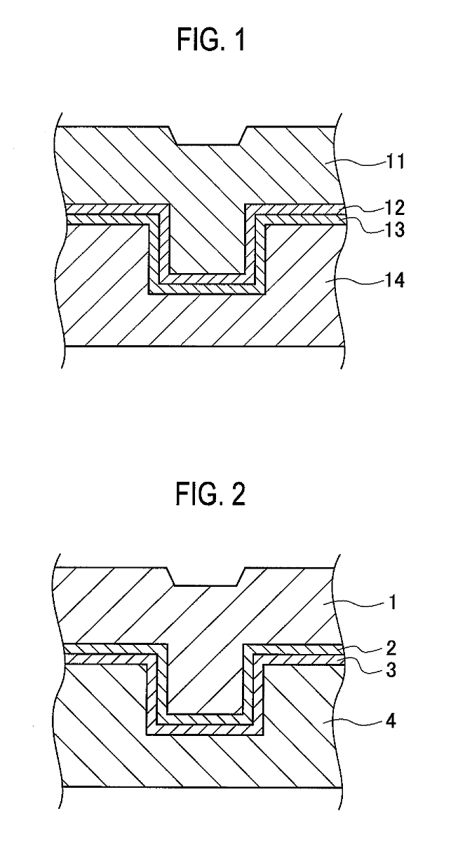

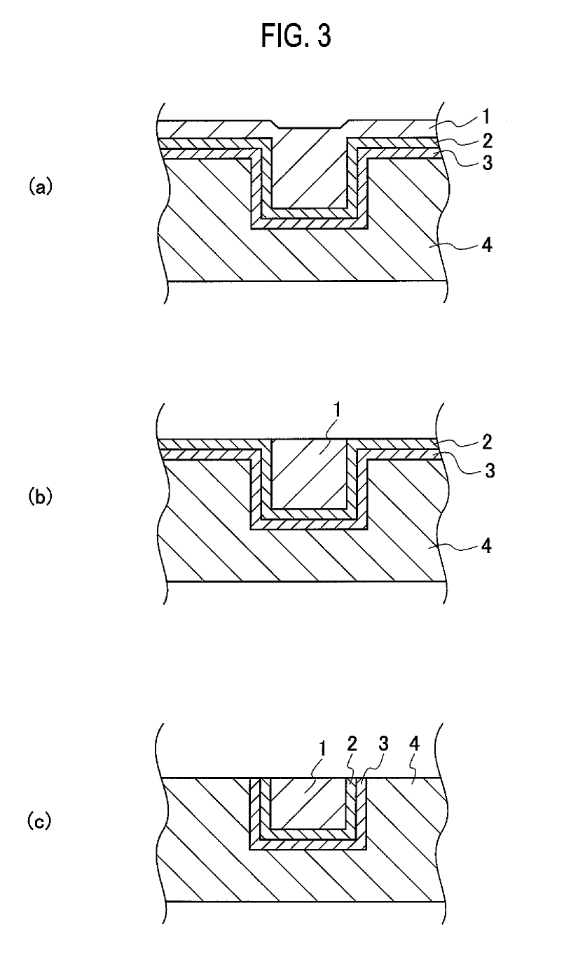

### BEST MODE FOR CARRYING OUT THE INVENTION

The best mode for carrying out the invention will be described in detail hereinafter.

The CMP polishing liquid of the invention comprising: an oxidizing agent; polishing particles; water; and a compound having a structure represented by the following Formula (1), which may be referred to as a “guanidine compound” hereinafter, or a salt thereof

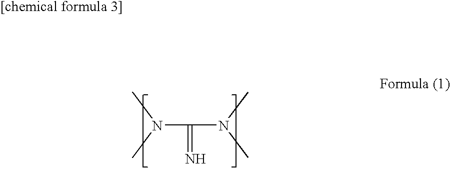

The compound having a structure represented by the Formula (1) (guanidine compound) may undergo resonance stabilization. It therefore appears that lone electron pairs which the N atoms have and the π electron pair of the double bond are stabilized so that the compound easily forms a complex with ruthenium.

As the guanidine compound or the salt thereof, a water-soluble guanidine compound or a salt thereof can be preferably used. The water-soluble guanidine compound or the salt thereof may be, for example, a guanidine compound which has a property represented generally by the wording “miscible freely with water”, “easily soluble in water”, “soluble in water” or the like, or a salt thereof, or may be a guanidine compound that is slightly soluble in water, which has a property represented generally by the wording “slightly soluble in water”, “poorly soluble in water” or the like, or salt thereof.

Specifically, the solubility of the guanidine compound or the salt thereof in water is preferably 0.005 mol/L or more. When the solubility in water is 0.005 mol/L or more, the ruthenium complex is good in solubility in water so that the effect of improving the polishing rate to ruthenium is easily obtained. The solubility in water is more preferably 0.01 mol/L or more, even more preferably 0.015 mol/L or more. The upper limit of the solubility in water is not particularly limited.

In the invention, the solubility of the guanidine compound or the salt thereof in water may be measured by a method prescribed in OECD GUIDELINE FOR THE TESTING OF CHEMICALS, 105, Water Solubility, Adopted by the Council on 27 Jul. 1995.

The guanidine compound or the salt thereof is preferably a compound represented by the following Formula (2), or a salt thereof, from the viewpoint of easy availability.

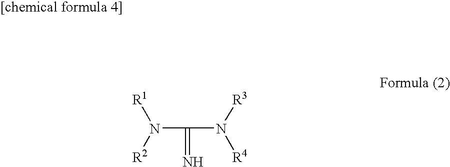

wherein R¹, R², R³ and R⁴ each independently represent a monovalent organic group.

In the Formula (2), specific examples of the monovalent organic group as R¹, R², R³ and R⁴ include a hydrogen atom, a hydroxyl group, alkyl groups having 1 to 3 carbon atoms, aryl groups, amino groups, an amide group (—C(═O)NH₂), an amidine group (—C(═NH)NH₂), a thioamide group (—C(═S)NH₂), a phenylsulfonyl group (—SO₂Ph) and the like. When R¹, R², Wand R⁴ are each other than a hydrogen atom, and a hydroxyl group, the main skeleton thereof may further have a substituent such as a hydroxyl group, an amino group, an alkyl group or the like.

Examples of the alkyl groups having 1 to 3 carbon atoms include methyl group, ethyl group, propyl group, isopropyl group and the like. The aryl groups are preferably aryl groups having 6 to 9 carbon atoms, and examples thereof include phenyl group, tolyl group, isopropylphenyl group and the like.

It is preferred that at least one of R¹, R², R³ and R⁴ is a hydroxyl group or amino group since the water-solubility of a ruthenium complex made from the ruthenium in a ruthenium layer is improved to enhance the polishing rate to the ruthenium layer. It is also preferred that at least one of R¹, R², R³ and R⁴ is an aryl group, amide group, amidine group, thioamide group or phenylsulfonyl group since the ruthenium complex is easily formed. It is presumed that such an advantageous effect is caused by a matter that the resonance skeleton is extended so that the lone electron pairs of the nitrogen atoms are stabilized.

In the invention, a salt of a compound (guanidine compound) having a structure represented by the Formula (1) may be used, and examples of the salt include the carbonate, hydrochloride, phosphate, nitrate, sulfate thereof and the like. Since it is undesired that a substrate is contaminated with a halide or the like, preferred are the carbonate, phosphate, nitrate, and sulfate.

About the guanidine compound, the number of atoms constituting its resonance structure is preferably 4 or more, more preferably 5 or more, and even more preferably 6 or more. When the number of the atoms is 4 or more, the complexing constant thereof with ruthenium tends to be able to be increased, thereby making it possible to make the polishing rate to a ruthenium layer large. The upper limit of the number of the atoms constituting the resonance structure is not particularly limited, and may be, for example, set to about 100 at most. In the invention, the wording “the number of atoms constituting a/the/its resonance structure” denotes the number of skeleton atoms except hydrogen atoms out of the atoms constituting the resonance structure.

Examples of the guanidine compound wherein the number of atoms constituting its resonance structure is 4 or more include guanidine (4), methylguanidine (4), hydroxyguanidine (5), 1,1-dimethylguanidine (4), 1,1-diethylguanidine (4), aminoguanidine (5, 0.05 mol/L), dicyandiamidine (7), guanylthiourea (7), phenylguanidine (10), phenylbiguanide (13), sulfaguanidine (14), o-tolylbiguanide (13, 0.015 mol/L), diphenylguanidine (16), and 1,3-di-o-tolylguanidine (16); and salts thereof. These may be used alone or in combination of two or more thereof. In the invention, guanidine carbonate, aminoguanidine bicarbonate, and o-tolylbiguanide are preferred. In any one of the examples, an integer in parentheses denotes the number of atoms constituting the resonance structure thereof. In some of the compounds, the solubility in water is also described.

The oxidizing agent contained in the CMP polishing liquid of the invention is a compound having an effect of oxidizing a metal. Examples of the oxidizing agent include hydrogen peroxide (H₂O₂), periodic acid, salts of periodic acid, salts of iodic acid, salts of bromic acid, salts of persulfuric acid, and cerium nitrate salts. Of the examples, hydrogen peroxide is particularly preferred. The salts are preferably potassium salts or ammonium salts.

These may be used alone or in combination of two or more thereof

When a substrate to be polished is a silicon substrate containing elements for integrated circuits, it is undesired that the substrate is contaminated with an alkali metal, an alkaline earth metal, a halide or the like; thus, the oxidizing agent is desirably an oxidizing agent which does not contain any nonvolatile component. However, when the target substrate is a glass substrate or the like, the oxidizing agent may be an oxidizing agent containing a nonvolatile component.

Examples of the polishing particles (abrasive grains) contained in the CMP polishing liquid of the invention include alumina, silica, ceria, titania and zirconia. Of these examples, alumina and silica are more preferred. Alumina is very good in the point that alumina is large in hardness to make it possible to polish ruthenium at a particularly high polishing rate. Silica is very good in the point that silica makes it possible to polish, in particular, a tantalum compound and an insulating film at a high polishing rate. Of these examples, a-alumina, fumed silica, and colloidal silica are in particular preferred. The polishing particles may be appropriately selected in accordance with the kind, the thickness and other factors of individual layers to be polished. The polishing particles are not limited to the above-mentioned examples. The examples may be used alone or in combination of two or more thereof.

The primary particle diameter of the polishing particles is preferably 200 nm or less, more preferably from 5 to 200 nm, in particular preferably from 5 to 150 nm, and highly preferably from 5 to 130 nm. When this primary particle diameter is 200 nm or less, even better planarity tends to be given to a metal layer and an insulating film layer.

When the polishing particles aggregate in the CMP polishing liquid, the secondary particle diameter is preferably 300 nm or less, more preferably from 10 to 300 nm, and in particular preferably from 10 to 200 nm. When this secondary particle diameter is 300 nm or less, even better planarity tends to be given to a metal layer and an insulating film layer. When the secondary particle diameter is 10 nm or more, it is possible to obtain sufficiently a capability that a reacted layer (oxidized layer) is mechanically removed by the polishing particles. Thus, the liquid tends to give very good polishing rates to a ruthenium layer, a barrier layer, an insulating film layer and a metal wiring layer.

In the invention, the primary particle diameter of the polishing particles may be measured by use of a transmission electron microscope (for example, S4700 manufactured by Hitachi Ltd.). When a primary particle is sandwiched between two parallel lines, the value of the region where the interval therebetween is the smallest is defined as the short diameter and the value of the region where the interval is the largest is defined as the long diameter. The average of the short diameter and the long diameter is defined as the primary particle diameter. About plural primary particles selected at will, the particle diameters are measured, and the arithmetic average thereof can be made into the primary particle diameter.

The secondary particle diameter in the polishing particles in the CMP polishing liquid may be measured by use of an optical diffraction scattering type particle size distribution meter (for example, COULTER N4SD, manufactured by COULTER Electronics Co.).

In the invention, a metal-oxide-dissolving agent may be added to the CMP polishing liquid. The metal-oxide-dissolving agent has an effect of dissolving a metal oxidized with the oxidizing agent. The metal-oxide-dissolving agent is preferably an acid. The metal-oxide-dissolving agent is not particularly limited as far as the agent is a water-soluble metal-oxide-dissolving agent. A compound different from the oxidizing agent is selected, and used. Examples thereof include organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, and citric acid; esters of these organic acids; and ammonium salts of these organic acids. Other examples thereof include inorganic acids such as hydrochloric acid, sulfuric acid, nitric acid, and phosphoric acid; ammonium salts of these inorganic acids, such as ammonium persulfate, ammonium nitrate, and ammonium chloride; and chromic acid. These may be used alone or in combination of two or more.

Of these examples, the following are suitable for polishing ruthenium layer since a practical polishing rate is maintained while the etching rate can be effectively restrained: formic acid, malonic acid, malic acid, maleic acid, tartaric acid, citric acid, phosphoric acid, and nitric aid.

In the invention, a metal anticorrosive may be added to the CMP polishing liquid. The metal anticorrosive is a compound for restraining a metal layer, in particular, a metal wiring layer from being etched to improve the dishing property. The metal anticorrosive is desirably one selected from the following group: ammonia and alkylamines, such as ammonia, dimethylamine, trimethylamine, triethylamine, propylenediamine, ethylenediaminetetraacetic acid (EDTA), sodium diethyldithiocarbamate and chitosan;

imines such as dithizone, cuproin (2,2′-biquinoline), neocuproine (2,9-dimethyl-1,10-phenanthroline), bathocuproine (2,9-dimethyl-4,7-diphenyl-1,10-phenanthroline), and cuperazone (biscyclohexanone oxalylhydrazone);

imidazoles such as benzimidazole-2-thiol;

triazines such as triazinedithiol, and triazinetrithiol;

thiazoles such as 2-[2-(benzothiazolyl)]thiopropionic acid, 2-[2-(benzothiazolyl)]thiobutyric acid, and 2-mercaptobenzothiazole);

azoles such as 1,2,3-trizole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazol, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolypmethyl]phosphonic acid;

mercaptans such as nonylmercaptan, and dodecylmercaptan; and glucose, and cellulose.

Of these examples, nitrogen-containing cyclic compounds such as imidazoles, triazines, thiazoles, and azoles are preferred for making a restraint of the etch rate of a metal layer compatible with the polishing rate to the metal layer. These may be used alone or in combination of two or more thereof.

In the invention, the content by percentage of the guanidine compound is preferably from 0.001 to 5% by mass of the whole of the polishing liquid. When this content by percentage is 0.001% or more by mass, the polishing rate to a ruthenium layer tends to be very good. From this viewpoint, the content by percentage is more preferably 0.005% or more by mass, in particular preferably 0.01% or more by mass. When the content by percentage is 5% or less by mass, the polishing rate tends to be improved in accordance with the addition amount. From this viewpoint, the content by percentage is more preferably 3% or less by mass, in particular preferably 1% or less by mass.

In the invention, the content by percentage of the oxidizing agent is preferably from 0.05 to 20% by mass of the whole of the polishing liquid. When the content by percentage is 0.05% or more by mass, a metal is sufficiently oxidized so that the polishing rate to a ruthenium layer, a barrier layer and a metal wiring layer tend to become large. From this viewpoint, the content by percentage is more preferably 0.1% or more by mass. When the content by percentage is 20% or less by mass, the polished surface tends to be prevented from being made rough. From this viewpoint, the content by percentage is more preferably 10% or less by mass, in particular preferably 5% or less by mass.

The content by percentage of the polishing particles is preferably from 0.01 to 20% by mass, more preferably from 0.01 to 15% by mass, and in particular preferably from 0.1 to 15% by mass of the whole of the polishing liquid.

When this content by percentage is 0.01% or more by mass, a sufficient physical grinding-away effect is also obtained so as to give large polishing rates to a ruthenium layer, a barrier layer, a metal wiring layer and an insulating film layer in CMP. When the content by percentage is 20% or less by mass, the polishing rate is increased in accordance with the addition.

The content by percentage of the metal-oxide-dissolving agent in the invention is preferably from 0.001 to 10% by mass of the whole of the polishing liquid. When this content by percentage is 0.001% or more by mass, the polishing rates to a ruthenium layer, a barrier layer and a metal wiring layer tend to become large in CMP. From this viewpoint, the content by percentage is more preferably 0.01% or more by mass, in particular preferably 0.02% or more by mass. When the content by percentage is 10% or less by mass, a metal wiring layer tends to be easily restrained from being etched when polished. From this viewpoint, the content by percentage is more preferably 8% or less by mass, in particular preferably 5% or less by mass.

In the invention, the content by percentage of the metal anticorrosive is preferably from 0.005 to 2% by mass of the whole of the polishing liquid. When this content by percentage is 0.005% or more by mass, a metal wiring layer tends to be easily restrained from being etched when polished. From this viewpoint, the content by percentage is more preferably 0.01% or more by mass, in particular preferably 0.02% or more by mass. When the content by percentage is 2% or less by mass, the polishing rate to a metal wiring layer tends to be sufficiently obtained. From this viewpoint, the content by percentage is more preferably 1% by mass, in particular preferably 0.5% or less by mass.

Into the CMP polishing liquid of the invention may be further incorporated a surfactant.

The pH of the CMP polishing liquid of the invention is preferably within the range of 2 or more and 12 or less to make the CMP polishing rate to a ruthenium layer large. If the pH is less than 2, the liquid is used without causing a problem but the polishing rates to a ruthenium layer, a barrier and an insulating film layer are small in CMP so that the polishing liquid does not easily become a practical polishing liquid. If the pH is more than 12, the liquid is used without causing a problem but the polishing rates to a ruthenium layer, a barrier layer and a metal wiring layer are small in CMP so that the polishing liquid does not easily become a practical polishing liquid. The pH is more preferably from 2 to 11, in particular preferably from 2 to 10.

Considering the balance between the polishing rates to the individual layers to be polished, the pH is preferably less than 7, for example, within the range of 3 to 5, in particular, near 4 (4±0.5) in some cases. However, the pH may be set under the consideration of the usage, polishing conditions and others. Thus, the pH is not limited to this range.

The following will describe the polishing method of the invention.

The polishing method of the invention is a method comprising the step of: polishing a surface of the substrate to be polished in the state of pushing the surface of the substrate to be polished against a polishing cloth on a polishing table and applying a predetermined pressure to the rear surface of the substrate (the surface opposite to the surface to be polished), while supplying the CMP polishing liquid of the invention between the surface to be polished and the polishing cloth by relatively moving the substrate and/or the polishing table.

An apparatus usable for the polishing is, for example, an ordinary polishing apparatus having: a table to which a motor making the rotating number variable, and the like are fitted and onto which the polishing cloth (pad) can be adhered; and a holder for holding the substrate. The polishing cloth is not particularly limited, and may be an ordinary nonwoven cloth, foamed polyurethane or porous fluorine-contained resin, or the like. Conditions for the polishing are not particularly limited; preferably, the rotating speed of the table is set to 200 rpm or less so as for the substrate not to spin out.

The pressure applied to the substrate pushed against the polishing cloth, that is polishing pressure, is preferably within the range of 4 to 100 kPa. The pressure is more preferably within the range of 6 to 50 kPa from the viewpoint of the evenness on the substrate surface, and the planarity of the pattern. When the CMP polishing liquid of the invention is used, a ruthenium layer can be polished at a high polishing rate under a low polishing pressure. The matter that polishing can be attained under a low polishing pressure is preferred from the viewpoint of the prevention of a layer to be polished from being peeled, chipped, made into small pieces or cracked, and the planarity of the pattern.

During the polishing, the CMP polishing liquid is continuously supplied to the polishing cloth by means of a pump or the like. The supply amount is not limited, and is preferably an amount such that the polishing cloth is constantly coated with the polishing liquid. After the polishing, it is preferred that the substrate is sufficiently washed with flowing water, water droplets adhering onto the substrate are wiped away by use of a spin drier or the like, and then the substrate is dried.

The substrate to be polished with the CMP polishing liquid of the invention is a substrate having a layer containing ruthenium, and is preferably a substrate obtained by forming, over a semiconductor wafer of silicon or the like, at least an insulating film layer, a barrier layer, a ruthenium layer, and a metal wiring layer in this order Generally, the insulating film layer has, in its surface, concave regions and convex regions based on grooves or holes where metal wiring is to be formed. The barrier layer covers the insulating film layer along the concave regions and the convex regions of the insulating film layer surface. Furthermore, the ruthenium layer covers the barrier layer along the concave regions and convex regions based on the insulating film layer. The metal wiring layer covers the ruthenium layer in the state that a metal is filled into the concave regions based on the insulating film layer.

The metal which the metal wiring layer is made of is preferably at least one selected from copper, copper alloys, copper oxides, or oxides of copper alloys. The metal wiring layer may be formed by publicly-known sputtering or plating.

The material which the layer containing ruthenium is made of is at least one selected from ruthenium, ruthenium alloys and other ruthenium compounds.

Specific examples of the ruthenium alloys include ruthenium tantalum alloy, and ruthenium titanium alloy. Specific example of the ruthenium compounds is ruthenium nitride.

The barrier layer is a layer for preventing an electroconductive material from diffusing into the insulating film layer. The material of which the barrier layer is made is not particularly limited as far as the material is ordinarily used as a material which constitutes a barrier layer. The material is at least one selected from tantalum, tantalum alloys, tantalum nitride, other tantalum compounds, titanium, titanium alloys, titanium nitride, other titanium compounds, tungsten, tungsten alloys, tungsten nitride, and other tungsten compounds.

The insulating film layer is not particularly limited as far as the layer is made of a material having electrically insulting property. A specific example thereof is a SiO₂ film, or an insulating film layer capable of making the parasitic capacitance between elements or between interconnections lower than any SiO₂ film.

The insulating film layer capable of making the parasitic capacitance between elements or between interconnections lower than any SiO₂ film is, for example, at least one selected from inorganic coated layer such as SiOF and Si—H containing SiO₂, organic-inorganic hybrid films such as carbon-containing SiO₂ (SiOC), and methyl-group-containing SiO₂, and organic polymer films such as Teflon (registered trademark) based polymers, polyimide based polymers, polyallyl ether based polymers, and parylene based polymers. When these are each made porous, the dielectric constant of the insulating film layer can be further decreased. However, it is known that to the accompaniment of such treatment by making these porous, the mechanical strength is further decreased; thus, it is preferred that such treatment is appropriately selected (see, for example, IEDM Tech. Digest Journal (1999), pp. 619-622).

An example of the process for polishing a substrate by use of the CMP polishing liquid of the invention includes a first polishing step of polishing the metal wiring layer present over convex regions of the insulating film layer to make the ruthenium layer uncovered, and a second polishing step of polishing the ruthenium layer and the barrier layer present over the convex regions of the insulating film layer, and the metal wiring layer buried in concave regions of the insulating film layer to make the convex regions of the insulating film layer uncovered. It is preferred to use the CMP polishing liquid of the invention at least in the second polishing step out of the two polishing steps. In the first polishing step, it is allowable that the metal wiring layer is caused to remain slightly not to make the ruthenium layer uncovered completely.

It is preferred that a film to be polished, which is a target to be polished with the CMP polishing liquid, includes at least the ruthenium layer, and includes one or more out of layers composed of the metal wiring layer, the barrier layer and the insulating film layer besides the ruthenium layer. In CMP under the same conditions, the polishing rate ratio of (the metal wiring layer/the ruthenium layer), that of (the metal wiring layer/the barrier layer), and that of (the metal wiring layer/the insulating film layer) are each preferably 1/(0.01−20).

If the polishing rate ratio is 1/(a value less than 0.01), the metal wiring layer is excessively polished to cause the generation of dishing, thereby tending to cause a problem that good damascene wiring cannot be formed. Moreover, the ruthenium layer, the barrier layer and the insulating film layer may not be polished at a sufficient rate so that in the second polishing step, much time tends to be required for removing unnecessary portions of the layers. If the polishing rate ratio is 1/(a value more than 20), the metal wiring layer may not be polished at a sufficient rate. Thus, when in the first polishing step in the two-stage polishing method the removal of the metal wiring layer in regions other than grooves or holes over the insulating film layer is incomplete, much time tends to be required for removing unnecessary portions of the metal wiring layer in the second polishing step.

When the target to be polished has plural layers, it is preferred that the CMP polishing liquid has the above-mentioned polishing rate ratios to each layer. In the case of polishing, for example, a film to be polished that has a metal wiring layer, a ruthenium layer or barrier layer, and an insulating film layer, it is preferred that the polishing rate ratio therebetween satisfies the following relationship: the ratio of (the metal wiring layer)/(the ruthenium layer or barrier layer)/(the insulating film layer) is 1/(0.01−20)/(0.01−20). This polishing rate is more preferably 1/(0.05−10)/(0.05−10), in particular preferably 1/(0.1−10)/(0.1−10).

### EXAMPLES

The invention will be described by way of examples hereinafter. The invention is not limited to these examples.

### Examples 1 to 8 and Comparative Examples 1 to 5

CMP polishing liquids of Examples 1 to 8 and Comparative Examples 1 to 5 were each prepared by incorporating 1.0 or 2% by mass of a species of abrasive grains shown in Table 1, 3.0% by mass of 30% hydrogen peroxide water, 0.1 or 0% by mass of one out of guanidine compounds shown in Table 1, 0.5 or 0% by mass of one out of acids shown in Table 1, 0.2% by mass of benzotriazole (BTA), and pure water as the balance, these contents by percentage being each a proportion in the mass of the polishing liquid, and incorporating ammonia for adjusting the pH. The solubility of each of the guanidine compounds in water was measured in accordance with OECD GUIDELINE FOR THE TESTING OF CHEMICALS, 105, Flask method descried above. The results are shown in Table 2.

These CMP polishing liquids were each used to polish each of substrates to be polished under conditions described below.

TABLE 1

| | Abrasive grains | Oxidizing agent | Guanidine compound | Acid | Metal anticorrosive | |
|---|---|---|---|---|---|---|
| No. | (% by mass) | (% by mass) | (% by mass) | (% by mass) | (% by mass) | pH |
| Example 1 | Colloidal silica | 30% Hydrogen peroxide water | Guanidine carbonate | Not contained | BTA | 6.2 |
| | (2.0) | (3.0) | (0.1) | | (0.2) | |
| Example 2 | Colloidal silica | 30% Hydrogen peroxide water | Guanidine carbonate | Phosphoric acid | BTA | 4.0 |
| | (2.0) | (3.0) | (0.1) | (0.5) | (0.2) | |
| Example 3 | Colloidal silica | 30% Hydrogen peroxide water | Guanidine carbonate | Malic acid | BTA | 4.0 |
| | (2.0) | (3.0) | (0.1) | (0.5) | (0.2) | |
| Example 4 | Colloidal silica | 30% Hydrogen peroxide water | Guanidine carbonate | Maleic acid | BTA | 4.0 |
| | (2.0) | (3.0) | (0.1) | (0.5) | (0.2) | |
| Example 5 | Colloidal silica | 30% Hydrogen peroxide water | Aminoguanidine | Maleic acid | BTA | 4.0 |
| | (2.0) | (3.0) | bicarbonate | (0.5) | (0.2) | |
| | | | (0.1) | | | |
| Example 6 | Colloidal silica | 30% Hydrogen peroxide water | o-Tolylbiguanide | Maleic acid | BTA | 4.0 |
| | (2.0) | (3.0) | (0.1) | (0.5) | (0.2) | |
| Example 7 | α Alumina | 30% Hydrogen peroxide water | Guanidine carbonate | Maleic acid | BTA | 4.0 |
| | (1.0) | (3.0) | (0.1) | (0.5) | (0.2) | |
| Example 8 | α Alumina | 30% Hydrogen peroxide water | o-Tolylbiguanide | Maleic acid | BTA | 4.0 |
| | (1.0) | (3.0) | (0.1) | (0.5) | (0.2) | |
| Comparative | Colloidal silica | 30% Hydrogen peroxide water | Not contained | Not contained | BTA | 7.6 |
| Example 1 | (2.0) | (3.0) | | | (0.2) | |
| Comparative | Colloidal silica | 30% Hydrogen peroxide water | Not contained | Phosphoric acid | BTA | 4.0 |
| Example 2 | (2.0) | (3.0) | | (0.5) | (0.2) | |
| Comparative | Colloidal silica | 30% Hydrogen peroxide water | Not contained | Malic acid | BTA | 4.0 |
| Example 3 | (2.0) | (3.0) | | (0.5) | (0.2) | |
| Comparative | Colloidal silica | 30% Hydrogen peroxide water | Not contained | Maleic acid | BTA | 4.0 |
| Example 4 | (2.0) | (3.0) | | (0.5) | (0.2) | |
| Comparative | α Alumina | 30% Hydrogen peroxide water | Not contained | Maleic acid | BTA | 4.0 |
| Example 5 | (1.0) | (3.0) | | (0.5) | (0.2) | |

TABLE 2

| | The number of | Solubility in water |
|---|---|---|
| Material name | resonance atoms | (mol/L) |
| Guanidine carbonate | 4 | 0.33 |
| Aminoguanidine bicarbonate | 5 | 0.05 |
| o-Tolylbiguanide | 13 | 0.015 |

(pH measurement)

Measuring temperature: 25±5° C.

Measuring device: a device manufactured by Denki Kagaku Keiki Ca, Ltd., model number: PHL-40

### (CMP Polishing Conditions)

Polishing apparatus: Mirra (manufactured by APPLIED MATERIALS Inc.)

Polishing liquid flow rate: 200 mL/minute

Substrates to be polished:

(1) a silicon substrate on which a copper film of 1.5 μm thickness was formed by sputtering

(2) a silicon substrate on which a ruthenium film of 0.3 μm thickness was formed by sputtering

(3) a silicon substrate on which a tantalum nitride film of 0.2 μm thickness was formed by sputtering

(4) a silicon substrate on which a silicon dioxide film of 1 μm thickness was formed by CVD

Polishing pad: a foamed polyurethane resin having independent foams (manufactured by Rodel Inc., model number: IC 1000)

Polishing pressure: 13.7 kPa

Relative speed between substrate and polishing table: 70 m/minute

Polishing period: 1 minute

Washing: after subjected to the CMP processing, each of the substrates was washed with a PVA blush and by ultrasonic wave water, and then dried with a spin drier.

### (Items for Evaluating the Polished Products)

Polishing rates: about each of the copper film (1), the ruthenium film (2) and the tantalum nitride film (3) out of the substrates (1) to (4) polished and washed under the above-mentioned conditions, the difference between the film thickness thereof before the polishing and that after the polishing was obtained by conversion from the electric resistance values. The difference between the film thickness of the silicon dioxide before the polishing and that after the polishing was measured with a film thickness measuring device (product name: LAMBDA ACE VLM 8000 LS) manufactured by Dainippon Screen Mfg. Co., Ltd. The polishing rates were calculated out from the measured film thickness differences.

In Table 3 are shown the polishing rate (R_{Cu}) to the copper film, the polishing rate (R_{Ru}) to the ruthenium film, the polishing rate (R_{TaN}) to the tantalum nitride film, the polishing rate (R_{SiO2}) to the SiO₂ film, the ratio of the polishing rate to the copper film to that to the ruthenium film (R_{Cu}/R_{Ru}), the ratio of the polishing rate to the copper film to that to the tantalum nitride film (R^{Cu}/R_{TaN}) and the ratio of the polishing rate (R_{Cu}) to the copper film to that (R_{SiO2}) to the SiO₂ film (R_{Ru}/R_{SiO2}) in each of Examples 1 to 8, and Comparative Examples 1 to 5.

Generation of polish scratches: each of the substrates after the CMP was observed with the naked eye, an optical microscope and an electron microscope to check whether not polish scratches were generated. As a result, in all of the Examples and Comparative Examples, remarkable generation of polish scratches was not recognized.

TABLE 3

| | R_{cu} | R_{Ru} | R_{TaN} | R_{SiO}_{₂} | | | |
|---|---|---|---|---|---|---|---|
| No | (nm/min.) | (nm/min.) | (nm/min.) | (nm/min.) | R_{cu}/R_{Ru} | R_{cu}/R_{TaN} | R_{cu}/R_{SiO}_{₂} |
| Example 1 | 12 | 23 | 2 | 2 | 0.52 | 6.0 | 6.0 |
| Example 2 | 220 | 45 | 50 | 22 | 4.9 | 4.4 | 10 |
| Example 3 | 40 | 32 | 40 | 18 | 1.3 | 1.0 | 2.2 |
| Example 4 | 17 | 31 | 41 | 21 | 0.55 | 0.41 | 0.81 |
| Example 5 | 18 | 40 | 33 | 20 | 0.45 | 0.55 | 0.90 |
| Example 6 | 20 | 72 | 34 | 22 | 0.28 | 0.59 | 0.91 |
| Example 7 | 25 | 60 | 41 | 12 | 0.42 | 0.61 | 2.1 |
| Example 8 | 35 | 72 | 43 | 10 | 0.49 | 0.81 | 3.5 |
| Comparative | 10 | 20 | 4 | 5 | 0.50 | 2.5 | 2.0 |
| Example 1 | | | | | | | |
| Comparative | 200 | 40 | 50 | 20 | 5.0 | 4.0 | 10 |
| Example 2 | | | | | | | |
| Comparative | 40 | 26 | 32 | 18 | 1.5 | 1.3 | 2.2 |
| Example 3 | | | | | | | |
| Comparative | 18 | 25 | 31 | 20 | 0.72 | 0.58 | 0.90 |
| Example 4 | | | | | | | |
| Comparative | 25 | 55 | 32 | 8 | 0.45 | 0.78 | 3.1 |
| Example 5 | | | | | | | |

The results shown in Table 3 will be described in detail hereinafter.

In Example 1, the same abrasive grains and oxidizing agent as in Comparative Example 1 were added, and further 0.1% by mass of guanidine carbonate was added as an additive. The abrasive grains were made of colloidal silica, and the oxidizing agent was 30% hydrogen peroxide water. In Example 1, the polishing rate to ruthenium was 23 nm/minute, which was a larger value than in Comparative Example 1. The ratio of the polishing rate to the copper film to that to the ruthenium film (R_{Cu}/R_{Ru}), the ratio of the polishing rate to the copper film to that to the tantalum nitride film (R_{Cu}/R_{TaN}), and the ratio of the polishing rate to the copper film to that to the SiO₂ film (R_{Cu}/R_{TaN}) were each in the range of 1/(0.1 to 10).

In Example 2, the same abrasive grains, oxidizing agent and acid as in Comparative Example 2 were added, and further 0.1% by mass of guanidine carbonate was added as an additive. The abrasive grains were made of colloidal silica, the oxidizing agent was 30% hydrogen peroxide water, and the acid was phosphoric acid. In Example 2, the polishing rate to ruthenium was 45 nm/minute, which was a larger value than in Comparative Example 2. The ratio of the polishing rate to the copper film to that to the ruthenium film (R_{Cu}/R_{Ru}), the ratio of the polishing rate to the copper film to that to the tantalum nitride film (R_{Cu}/R_{TaN}), and the ratio of the polishing rate to the copper film to that to the SiO₂ film (R_{Cu}/R_{SiO2}) were each in the range of 1/(0.1 to 10).

In Example 3, the same abrasive grains, oxidizing agent and acid as in Comparative Example 3 were added, and further 0.1% by mass of guanidine carbonate was added as an additive. The abrasive grains were made of colloidal silica, the oxidizing agent was 30% hydrogen peroxide water, and the acid was malic acid. In Example 3, the polishing rate to ruthenium was 32 nm/minute, which was a larger value than in Comparative Example 3. The ratio of the polishing rate to the copper film to that to the ruthenium film (R_{Cu}/R_{Ru}), the ratio of the polishing rate to the copper film to that to the tantalum nitride film (R_{Cu}/R_{TaN}), and the ratio of the polishing rate to the copper film to that to the SiO₂ film (R_{Cu}/R_{SiO2}) were each in the range of 1/(0.1 to 10).

In Examples 4 to 6, the same abrasive grains, oxidizing agent and acid as in Comparative Example 4 were added, and further 0.1% by mass of one of the guanidine compounds shown in Table 1 was added as an additive. The abrasive grains were made of colloidal silica, the oxidizing agent was 30% hydrogen peroxide water, and the acid was maleic acid. In each of the Examples, the polishing rate to ruthenium was a larger value than in Comparative Example 4. The ratio of the polishing rate to the copper film to that to the ruthenium film (R_{Cu}/R_{Ru}), the ratio of the polishing rate to the copper film to that to the tantalum nitride film (R_{Cu}/R_{TaN}), and the ratio of the polishing rate to the copper film to that to the SiO₂ film (R_{Cu}/R_{SiO2}) were each in the range of 1/(0.1 to 10).

In Examples 7 and 8, the same abrasive grains, oxidizing agent and acid as in Comparative Example 5 were added, and further one of the guanidine compounds shown in Table 1 was added as an additive. The abrasive grains were made of α-alumina, the oxidizing agent was 30% hydrogen peroxide water, and the acid was maleic acid. In each of the Examples, the polishing rate to ruthenium was a larger value than in Comparative Example 5. The ratio of the polishing rate to the copper film to that to the ruthenium film (R_{Cu}/R_{Ru}), the ratio of the polishing rate to the copper film to that to the tantalum nitride film (R_{Cu}/R_{TaN}), and the ratio of the polishing rate to the copper film to that to the SiO₂ film (R_{Cu}/R_{SiO2}) were each in the range of 1/(0.1 to 10).

In all of the polishing liquids of Examples 1 to 8, the addition of a guanidine compound or a salt thereof made it possible to make the polishing rates better than in the polishing liquids of Comparative Examples 1 to 5 corresponding to the prior art. As is understood from Examples 1 to 8, the use of a polishing liquid to which a guanidine compound or a salt thereof was added made it possible to polish each of the metal wiring layer, the ruthenium layer, the barrier layer and the insulating film layer at a desired rate.

According to the polishing liquid of the invention, a ruthenium layer can be polished at a high polishing rate, and further each of a metal wiring layer, a ruthenium layer, a barrier layer and an insulating film layer can be polished at a desired rate so that the dishing of the metal wiring layer and the erosion of the barrier layer and the insulating film layer can be restrained.

### [Examples 9 to 15, and Comparative Examples 6 to 9]

CMP polishing liquids of Examples 9 to 12 and Comparative Example 6 were each prepared by incorporating 1.0% by mass of colloidal silica, 3.0% by mass of one out of oxidizing agents shown in Table 4, 0.1% by mass of a guanidine compound shown in Table 4, 0.5% by mass of an acid shown in Table 4, 0.2% by mass of benzotriazole, and pure water as the balance, these contents by percentage being each a proportion in the mass of the polishing liquid, and incorporating ammonia for adjusting the pH.

CMP polishing liquids of Examples 13 to 15 and Comparative Examples 7 to 9 were each prepared by incorporating 1.0% by mass of colloidal silica, 3.0% by mass of an oxidizing agent shown in Table 5, 0.1% by mass of a guanidine compound shown in Table 5, 0.5% by mass of an acid shown in Table 5, 0.2% by mass of benzotriazole, and pure water as the balance, these contents by percentage being each a proportion in the mass of the polishing liquid, and incorporating ammonia for adjusting the pH.

These CMP polishing liquids were each used to polish each of substrates to be polished under conditions described below.

TABLE 4

| | Abrasive grains | Oxidizing agent | Guanidine compound | Acid | Metal anticorrosive | |
|---|---|---|---|---|---|---|
| No. | (% by mass) | (% by mass) | (% by mass) | (% by mass) | (% by mass) | pH |
| Example 9 | Colloidal silica | 30% Hydrogen peroxide water | Guanidine carbonate | Malic acid | BTA | 4.0 |
| | (1.0) | (3.0) | (0.1) | (0.5) | (0.2) | |
| Example 10 | Colloidal silica | Potassium iodate | Guanidine carbonate | Malic acid | BTA | 4.0 |
| | (1.0) | (3.0) | (0.1) | (0.5) | (0.2) | |
| Example 11 | Colloidal silica | Periodic acid | Guanidine carbonate | Malic acid | BTA | 4.0 |
| | (1.0) | (3.0) | (0.1) | (0.5) | (0.2) | |
| Example 12 | Colloidal silica | Cerium ammonium nitrate | Guanidine carbonate | Malic acid | BTA | 4.0 |
| | (1.0) | (3.0) | (0.1) | (0.5) | (0.2) | |
| Comparative | Colloidal silica | Not contained | Guanidine carbonate | Malic acid | BTA | 4.0 |
| Example 6 | (1.0) | | (0.1) | (0.5) | (0.2) | |

For reference, about potassium iodate or periodic acid, the salt or acid itself was added in a proportion of 3.0% by mass.

TABLE 5

| | Abrasive grains | Oxidizing agent | Guanidine compound | Acid | Metal anticorrosive | |
|---|---|---|---|---|---|---|
| No. | (% by mass) | (% by mass) | (% by mass) | (% by mass) | (% by mass) | pH |
| Example 13 | Colloidal silica | 30% Hydrogen peroxide water | Guanidine carbonate | Malic acid | BTA | 4.0 |
| | (1.0) | (3.0) | (0.1) | (0.5) | (0.2) | |
| Example 14 | Colloidal silica | 30% Hydrogen peroxide water | Guanidine carbonate | Malic acid | BTA | 7.0 |
| | (1.0) | (3.0) | (0.1) | (0.5) | (0.2) | |
| Example 15 | Colloidal silica | 30% Hydrogen peroxide water | Guanidine carbonate | Malic acid | BTA | 9.4 |
| | (1.0) | (3.0) | (0.1) | (0.5) | (0.2) | |
| Comparative | Colloidal silica | 30% Hydrogen peroxide water | Not contained | Malic acid | BTA | 4.0 |
| Example 7 | (1.0) | (3.0) | | (0.5) | (0.2) | |
| Comparative | Colloidal silica | 30% Hydrogen peroxide water | Not contained | Malic acid | BTA | 7.0 |
| Example 8 | (1.0) | (3.0) | | (0.5) | (0.2) | |
| Comparative | Colloidal silica | 30% Hydrogen peroxide water | Not contained | Malic acid | BTA | 9.4 |
| Example 9 | (1.0) | (3.0) | | (0.5) | (0.2) | |

(pH measurement)

Measuring temperature: 25±5° C.

Measuring device: a device manufactured by Denki Kagaku Keiki Co., Ltd., model number: PHL-40

### (CMP Polishing Conditions)

Polishing apparatus: a desktop lapping instrument (manufactured by Nano Factor Co., Ltd.)

Polishing liquid flow rate: 11 mL/minute

Substrates to be polished: a silicon substrate on which a ruthenium film of 0.3 μm thickness was formed by sputtering, and

a silicon substrate on which a silicon dioxide film of 1 μm thickness was formed by CVD

Polishing pad: a foamed polyurethane resin having independent foams (manufactured by Rodel Inc., model number: IC 1000)

Polishing pressure: 29.4 kPa

Relative speed between substrate and polishing table: 25 m/minute

Polishing period: 1 minute

Washing: after polished, each of the wafers was sufficiently washed with flowing water, and then water droplets thereon were removed to dry the wafer.

### (Items for Evaluating the Polished Products)

Polishing rates: about the ruthenium film polished and washed under the above-mentioned conditions, the difference between the film thickness thereof before the polishing and that after the polishing was obtained by conversion from the electric resistance values. About the silicon dioxide film polished and washed under the above-mentioned conditions, the difference between the film thickness thereof before the polishing and that after the polishing was measured with a film thickness measuring device (product name: LAMBDA ACE VLM 8000 LS) manufactured by Dainippon Screen Mfg. Co., Ltd. The polishing rates were calculated out from the measured film thickness differences.

The Ru polishing rates in Examples 9 to 12 and Comparative Example 6 are shown in Table 6.

TABLE 6

| | Rcu Polishing rate |
|---|---|
| No | (nm/min.) |
| Example 9 | 16.1 |
| Example 10 | 17.4 |
| Example 11 | 15.3 |
| Example 12 | 2.5 |
| Comparative Example 6 | 0.1 |

The results shown in Table 6 will be descried in detail hereinafter.

In Example 9, the same guanidine compound and acid as in Comparative Example 6 were added, and further 3.0% by mass of 30% hydrogen peroxide water was added as the oxidizing agent. The used guanidine compound was guanidine carbonate, and the acid was malic acid. In Example 9, the polishing rate was 16.1 nm/minute, which was more than 100 times larger than that in Comparative Example 6.

In Example 10, the same guanidine compound and acid as in Comparative Example 6 were added, and further 3.0% by mass of potassium iodate was added as the oxidizing agent. The used guanidine compound was guanidine carbonate, and the acid was malic acid. In Example 10, the polishing rate was 17.4 nm/minute, which was more than 100 times larger than that in Comparative Example 6.

In Example 11, the same guanidine compound and acid as in Comparative Example 6 were added, and further 3.0% by mass of periodic acid was added as the oxidizing agent. The used guanidine compound was guanidine carbonate, and the acid was malic acid. In Example 11, the polishing rate was 15.3 nm/minute, which was more than 100 times larger than that in Comparative Example 6.

In Example 12, the same guanidine compound and acid as in Comparative Example 6 were added, and further 3.0% by mass of cerium ammonium nitrate was added as the oxidizing agent. The used guanidine compound was guanidine carbonate, and the acid was malic acid. In Example 12, the polishing rate was 2.5 nm/minute, which was more than 20 times larger than that in Comparative Example 6.

In all of Examples 9 to 12, which were each a polishing liquid containing an oxidizing agent, polishing particles, water, a guanidine compound or salt thereof, a higher polishing rate was obtained than in Comparative Example 6, which was a polishing liquid containing no oxidizing agent.

The Ru polishing rates and the SiO₂ polishing rates in Examples 13 to 15 and Comparative Examples 7 to 9 are shown in Table 7.

TABLE 7

| | Rcu Polishing rate | RSiO₂ Polishing rate |
|---|---|---|
| No | (nm/min.) | (nm/min.) |
| Example 13 | 16.1 | 12.1 |
| Example 14 | 18.8 | 4.9 |
| Example 15 | 19.9 | 1.3 |
| Comparative Example 7 | 14.2 | 12.2 |
| Comparative Example 8 | 16.5 | 1.4 |
| Comparative Example 9 | 17.5 | 1.1 |

The results shown in Table 7 will be described in detail hereinafter.

In Example 13, the same oxidizing agent and acid as in Comparative Example 7 were added, and further 0.1% by mass of guanidine carbonate was added as an additive. The oxidizing agent was 30% hydrogen peroxide water, and the acid was malic acid. The pH of the polishing liquid was adjusted to 4.0 with ammonia. In Example 13, the Ru polishing rate was 16.1 nm/minute, which was larger than that in Comparative Example 7. The SiO₂ polishing rate was 12.1 nm/minute, which was equivalent to that in Comparative Example 7. In Example 13, about the Ru polishing rate and SiO₂ polishing rate, equivalent polishing rates were obtained.

In Example 14, the same oxidizing agent and acid as in Comparative Example 8 were added, and further 0.1% by mass of guanidine carbonate was added as an additive. The oxidizing agent was 30% hydrogen peroxide water, and the acid was malic acid. The pH of the polishing liquid was adjusted to 7.0 with ammonia. In Example 14, the Ru polishing rate was 18.8 nm/minute, which was larger than that in Comparative Example 8. The SiO₂ polishing rate was 4.9 nm/minute, which was larger than that in Example 8.

In Example 15, the same oxidizing agent and acid as in Comparative Example 9 were added, and further 0.1% by mass of guanidine carbonate was added as an additive. The oxidizing agent was 30% hydrogen peroxide water, and the acid was malic acid. The pH of the polishing liquid was adjusted to 9.4 with ammonia. In Example 15, the Ru polishing rate was 19.9 nm/minute, which was larger than that in Comparative Example 9. The SiO₂ polishing rate was 1.3 nm/minute, which was equivalent to that in Example 9.

In all of the polishing liquids of Examples 13 to 15, the addition of a guanidine compound or a salt thereof made it possible to make the polishing rates better than in the polishing liquids of Comparative Examples 7 to 9 corresponding to the prior art regardless of the pH of the polishing liquids.

### INDUSTRIAL APPLICABILITY

According to the polishing liquid and the polishing method of the invention, the polishing rate to a ruthenium layer can be made better than according to a case wherein the conventional polishing liquid or polishing method is used. Furthermore, according to one embodiment of the polishing liquid and the polishing method of the invention, in the case of polishing a metal wiring layer, a barrier layer, an insulating film layer and others besides the ruthenium layer, each of the metal wiring layer, the ruthenium layer, the barrier layer, and the insulating film layer can be polished at a desired polishing rate as well as the polishing rate to the ruthenium layer can be improved.

1. A CMP polishing liquid for polishing a substrate having a layer containing ruthenium, comprising: an oxidizing agent; polishing particles; water; and a compound having a structure represented by the following Formula (1), or a salt thereof.

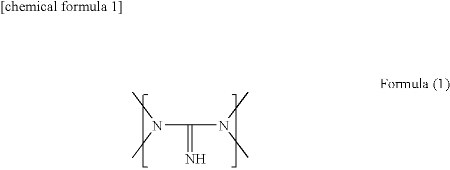

2. The CMP polishing liquid according to claim 1, wherein the compound is represented by the following Formula (2), 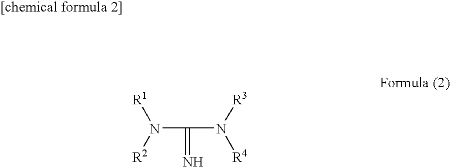
wherein R¹, R², R³ and R⁴ each independently represent a monovalent organic group.

3. The CMP polishing liquid according to claim 1, wherein the oxidizing agent contains at least one selected from the group consisting of hydrogen peroxide, periodic acid, salts of periodic acid, salts of iodic acid, salts of bromic acid, salts of persulfuric acid, and cerium nitrate salts.

4. The CMP polishing liquid according to claim 1, wherein the polishing particles contain at least one selected from the group consisting of alumina, silica, ceria, titania, and zirconia.

5. The CMP polishing liquid according to claim 1, further comprising a metal-oxide-dissolving agent.

6. The CMP polishing liquid according to claim 1, wherein the compound has 4 or more atoms constituting a resonance structure.

7. A method for polishing a substrate, comprising the step of: polishing a surface of the substrate to be polished in the state of pushing the surface of the substrate to be polished against a polishing cloth on a polishing table and applying pressure to the substrate from the substrate surface opposite to the surface to be polished, while supplying a CMP polishing liquid as recited in claim 1 between the surface to be polished and the polishing cloth by moving the substrate and/or the polishing table.
